(19) United States
(12) Patent Application Publication
(10) Pub. No.: US 2022/0269280 A1
(43) Pub. Date: Aug. 25, 2022

(54) TRAVELING VEHICLE, TRAVELING VEHICLE SYSTEM, AND TRAVELING VEHICLE DETECTION METHOD

(71) Applicant: MURATA MACHINERY, LTD., Kyoto-shi, Kyoto (JP)

(72) Inventors: Seiji YAMAGAMI, Kyoto-shi (JP); Munekuni OSHIMA, Ise-shi (JP)

(21) Appl. No.: 17/625,358

(22) PCT Filed: May 20, 2020
(86) PCT No.: PCT/JP2020/019962

§ 371 Date: Jan. 7, 2022

(30) Foreign Application Priority Data
Jul. 17, 2019 (JP) 2019-131976

(51) Int. Cl. G05D 1/02; G06V 20/58; G06V 20/20; G06V 30/224

(52) U.S. Cl. CPC G05D 1/0238; G05D 1/0246; G05D 1/0287; G06V 20/58; G06V 20/20; G06V 30/224; G05D 2201/0216

(57) ABSTRACT

A main body portion of a traveling vehicle includes large area symbols and a small area symbol having an area smaller than an area of each of the large area symbols which each have a size that does not entirely fit within an image capturing range of an imager located on a following traveling vehicle at a position less than a predetermined distance from the traveling vehicle. The small area symbol has a size that entirely fits within the image capturing range of the imager located on the following traveling vehicle even if the distance between the traveling vehicle and the following traveling vehicle is less than the predetermined distance. A determiner determines that, when at least one of the entire large area symbols and the entire small area symbol is extracted from a captured image, a preceding traveling vehicle is present.

### BACKGROUND OF THE INVENTION

### 1. Field of the Invention

One aspect of the present invention relates to a traveling vehicle, a traveling vehicle system, and a traveling vehicle detection method.

### 2. Description of the Related Art

A transport vehicle system in which a plurality of transport vehicles travel on a predetermined path has been known. For example, in Japanese Unexamined Patent Publication No. H11-202940, disclosed is a transport vehicle system (traveling vehicle system) in which a transport vehicle (traveling vehicle) is monitored by a sensor, the distance to the traveling vehicle is compared with a remaining traveling distance and, if the remaining distance is shorter than the distance to the traveling vehicle, the traveling vehicle is allowed to continue traveling at a low speed.

### SUMMARY OF THE INVENTION

In the above-described conventional traveling vehicle system, in addition to a linear inter-vehicle distance sensor that measures the distance to a carriage in front in the linear section, a curved inter-vehicle distance sensor that measures the distance to the carriage in front in a curved section is provided. Providing such a plurality of sensors has been a cause of high cost.

Preferred embodiments of the present invention provide traveling vehicles, traveling vehicle systems, and traveling vehicle detection methods each capable of achieving cost reduction.

A traveling vehicle according to one aspect of a preferred embodiment of the present invention is a traveling vehicle capable of traveling along a predetermined traveling path, and includes a main body portion provided with a symbol visible from a following traveling vehicle located behind the traveling vehicle, an imager positioned in or on the main body portion so that an image capturing range is in front of the traveling vehicle, and a determiner to attempt an extraction of the symbol from a captured image acquired by the imager and to determine, based on whether the symbol has been extracted, whether a preceding traveling vehicle located in front of the traveling vehicle is present, in which the main body portion is provided with, as the symbol, a large symbol and a small symbol having a smaller area than that of the large symbol, the large symbol has a size that does not entirely fit within an image capturing range of an imager provided in or on the following traveling vehicle located less than a predetermined distance from the traveling vehicle, the small symbol has a size that entirely fits within the image capturing range of the imager provided in or on the following traveling vehicle even if a distance from between traveling vehicle and the following traveling vehicle is less than the predetermined distance, and the determiner is configured or programmed to determine that, when at least one of the entire large symbol and the entire small symbol is extracted from the captured image, the preceding traveling vehicle is present.

A traveling vehicle detection method according to one aspect of a preferred embodiment of the present invention is a method of detecting a preceding traveling vehicle located in front of a traveling vehicle, based on a captured image acquired by an imager positioned in or on the traveling vehicle such that an image capturing range of the imager is in front of the traveling vehicle, the method including installing, at a region of the traveling vehicle visible from a following traveling vehicle located behind the traveling vehicle, a large symbol having a size that does not entirely fit within an image capturing range of an imager located in or on the following traveling vehicle located less than a predetermined distance from the following traveling vehicle, and a small symbol having a size that entirely fits within the image capturing range of the imager provided in or on the following traveling vehicle even if a distance between the traveling vehicle and the following traveling vehicle is less than the predetermined distance, acquiring a captured image of the preceding traveling vehicle by the imager of the traveling vehicle, attempting to extract an entirety of the large symbol and an entirety of the small symbol from the captured image, and determining that, when at least one of the entirety of the large symbol and the entirety of the small symbol is extracted, the preceding traveling vehicle is present.

In this case, “the symbol entirely fits within the image capturing range” includes not only the case of being captured in a size that is extracted by the determiner but also the case of being captured in a size that is not extracted by the determiner. In the above-described traveling vehicle and the traveling vehicle detection method, the imager having a wider image capturing range relative to the range of capturing a traveling vehicle in front by sensors provided corresponding to each section of a linear section and a curved section is provided. Thus, without providing an imager to each of the linear section and the curved section as in the conventional case, a preceding traveling vehicle located in both sections can be captured with a single imager. Meanwhile, in the above-described traveling vehicle and the traveling vehicle detection method, although the imager does not have a function of measuring the distance, the determiner that determines the distance to the preceding traveling vehicle based on the captured image of the symbol of the preceding traveling vehicle captured by the imager determines the distance to the preceding traveling vehicle. This allows a single imager to serve a function equivalent to that of the conventional sensor provided corresponding to each section of the linear section and the curved section. As a result, cost reduction can be achieved.

In a traveling vehicle according to one aspect of a preferred embodiment of the present invention, the determiner may determine that the determiner is in a first state when only the large symbol was able to be extracted, is in a second state when both the small symbol and the large symbol were able to be extracted, and is in a third state when only the small symbol was able to be extracted, and the determiner may determine that the distance between the traveling vehicle and the preceding traveling vehicle when determined to be in the second state is shorter than when determined to be in the first state and that the distance from the traveling vehicle to the preceding traveling vehicle when determined to be in the third state is shorter than when determined to be in the second state. With this configuration, even when an imager not having a function of measuring the distance to an imaged object is used, the distance between the traveling vehicle and the preceding traveling vehicle can be acquired in three stages (long distance, medium distance, short distance).

In a traveling vehicle according to one aspect of a preferred embodiment of the present invention, the small symbol may include a graphic including two colors. With this configuration, the determiner is likely to easily extract the symbol as a small symbol from the captured image.

In a traveling vehicle according to one aspect of a preferred embodiment of the present invention, the small symbol may include a two-dimensional code. With this configuration, because more information can be provided to the traveling vehicle, the traveling vehicle can be controlled more finely.

In a traveling vehicle according to one aspect of a preferred embodiment of the present invention, the small symbol may be an Augmented Reality (AR) marker capable of providing to the determiner a distance to the imager. In this case, the determiner can acquire the relative distance to and from the preceding traveling vehicle, and thus, can control the traveling vehicle more finely.

In a traveling vehicle according to one aspect of a preferred embodiment of the present invention, the large symbol may include a graphic including two colors. With this configuration, the determiner is likely to easily extract the symbol as a large symbol from the captured image.

In ae traveling vehicle according to one aspect of a preferred embodiment of the present invention, the large symbol may include a two-dimensional code. With this configuration, because more information can be provided to the traveling vehicle, the traveling vehicle can be controlled more finely.

In a traveling vehicle according to one aspect of a preferred embodiment of the present invention, the large symbol may be an AR marker capable of providing to the determiner a distance to the imager. In this case, the determiner can acquire the relative distance to and from the preceding traveling vehicle, and thus, can control the traveling vehicle more finely.

In a traveling vehicle according to one aspect of a preferred embodiment of the present invention, a plurality of the large symbols may be provided in the main body portion. With this configuration, because redundancy can be provided, the determiner can acquire information more accurately from the large symbols.

In a traveling vehicle according to one aspect of a preferred embodiment of the present invention, the main body portion includes a front surface portion and a rear surface portion in front and rear of a traveling direction of the traveling vehicle, the large symbol includes an appearance of the rear surface portion, the determiner may extract the large symbol based on a recognition result of an image recognizer that recognizes an appearance image of the rear surface portion, and the image recognizer includes a memory to store each of a plurality of image features detected from the appearance image of the rear surface portion as a portion in advance, a feature detector to detect a plurality of image features from an input image, a restorer to select the portion corresponding to each of the image features detected in the feature determiner from the memory and to generate a restoration image by using the plurality of selected portions, and a determiner configured or programmed to determine whether the restoration image generated in the restorer matches the input image by a matching process and to recognize that, when determined that the restoration image matches the input image, the input image is the appearance image of the rear surface portion.

With this configuration, when generating the restoration image, the portions detected from the image of the rear surface portion are used. Consequently, when an image other than the appearance image is input as an input image, it is not possible to correctly generate the input image as the restoration image. Thus, by determining whether the input image matches with the restoration image, the match or mismatch between the input image and the appearance image of the rear surface portion (whether the input image is the appearance image of the rear surface portion or other images) can be determined with high accuracy. That is, it is possible to recognize the appearance image of the rear surface portion with high accuracy.

In a traveling vehicle according to one aspect of a preferred embodiment of the present invention, the imager may include at least one of a LIDAR (Light Detection and Ranging) device, a stereo camera, a Time of Flight (TOF) camera, and a millimeter-wave radar. With this configuration, the determiner can more accurately calculate the distance to the small symbol and the large symbol. As a result, the traveling vehicle can be controlled more finely.

A traveling vehicle system according to one aspect of a preferred embodiment of the present invention may include a plurality of the above-described traveling vehicles. Each of the traveling vehicles of the traveling vehicle system in this configuration is provided with the imager having a wider image capturing range relative to the range of capturing the traveling vehicle in front by sensors provided corresponding to each section of the linear section and the curved section, there is no need to provide an imager to each section of the linear section and the curved section as in the conventional case. Without providing an imager to each section of the linear section and the curved section as in the conventional case, the preceding traveling vehicle located in both sections can be captured. Meanwhile, with this configuration, although the imager does not have the function of measuring the distance, the determiner that determines the distance to the preceding traveling vehicle based on the captured image of the symbol of the preceding traveling vehicle by the imager acquires the distance to the preceding traveling vehicle. This allows a single imager to serve a function equivalent to that of a sensor provided corresponding to each section of the linear section and the curved section. As a result, cost reduction of one traveling vehicle can be achieved, and eventually, the cost reduction of the entire traveling vehicle system can be achieved.

According to various preferred embodiments of the present invention, cost reduction can be achieved.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a schematic configuration diagram illustrating a traveling vehicle system according to a first preferred embodiment of the present invention.

FIG. 2 is a side view illustrating a traveling vehicle in the traveling vehicle system according to the first preferred embodiment of the present invention.

FIG. 3 is a rear view of a main body portion of the traveling vehicle in FIG. 1 as viewed from the rear in a traveling direction.

FIG. 4 is a block diagram illustrating a functional configuration of the traveling vehicle in FIG. 1.

FIG. 5 is a flowchart illustrating a traveling vehicle detection method according to the first preferred embodiment of the present invention.

FIG. 6 is a block diagram illustrating a functional configuration of a traveling vehicle according to a second preferred embodiment of the present invention.

FIG. 7 is a diagram for explaining one example of detecting a plurality of image features from an input image by a feature detector of an image recognizer in FIG. 6.

FIG. 8 is a diagram for explaining one example of generating a restoration image by a restorer of the image recognizer in FIG. 6.

FIG. 9A is a diagram illustrating one example of a captured image. FIG. 9B is a diagram illustrating one example of depth distance data.

FIG. 10A is a diagram illustrating one example of an input image. FIG. 10B is a diagram illustrating a restoration image restored from the input image in FIG. 9A.

FIG. 11A is a diagram illustrating one example of an input image. FIG. 11B is a diagram illustrating a restoration image restored from the input image in FIG. 11A.

FIG. 12A is a diagram illustrating one example of an input image. FIG. 12B is a diagram illustrating a restoration image restored from the input image in FIG. 12A. FIG. 12C is a diagram illustrating one example of an input image. FIG. 12D is a diagram illustrating a restoration image restored from the input image in FIG. 12C. FIG. 12E is a diagram illustrating one example of an input image. FIG. 12F is a diagram illustrating a restoration image restored from the input image in FIG. 12E. FIG. 12G is a diagram illustrating one example of an input image. FIG. 12H is a diagram illustrating a restoration image restored from the input image in FIG. 12G. FIG. 12I is a diagram illustrating one example of an input image. FIG. 12J is a diagram illustrating a restoration image restored from the input image in FIG. 12I.

FIG. 13 is a rear view of a main body portion of the traveling vehicle according to a modification as viewed from the rear in the traveling direction.

### DETAILED DESCRIPTION OF THE PREFERRED EMBODIMENTS

With reference to the accompanying drawings, the following describes preferred embodiments of the present invention in detail. In the description of the drawings, identical elements will be denoted by identical reference signs and redundant explanations will be omitted.

### First Preferred Embodiment

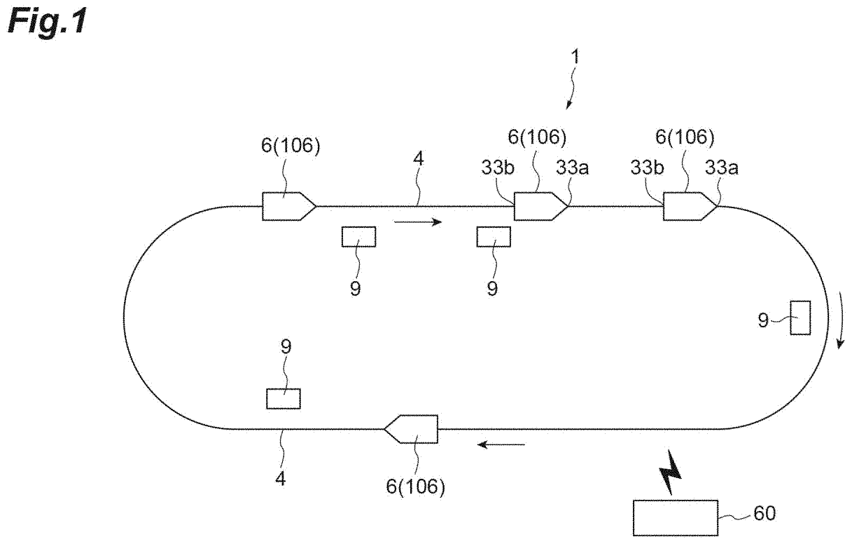

With reference to FIG. 1 to FIG. 5 mainly, a first preferred embodiment of the present invention will be described. A traveling vehicle system 1 is a system to transport, by using an overhead traveling vehicle 6 capable of moving along a track (predetermined traveling path) 4, an article 10 between placement portions 9 and 9. The article 10 includes a container such as a FOUP (Front Opening Unified Pod) to store a plurality of semiconductor wafers and a reticle pod to store a glass substrate, and general components and the like, for example. In this case, the traveling vehicle system 1 in which, for example, the overhead traveling vehicle 6 (hereinafter, referred to simply as “traveling vehicle 6”) travels along the one-way track 4 that may be laid on a ceiling or the like of a factory will be described as an example. As illustrated in FIG. 1, the traveling vehicle system 1 includes the track 4, a plurality of placement portions 9, and a plurality of traveling vehicles 6.

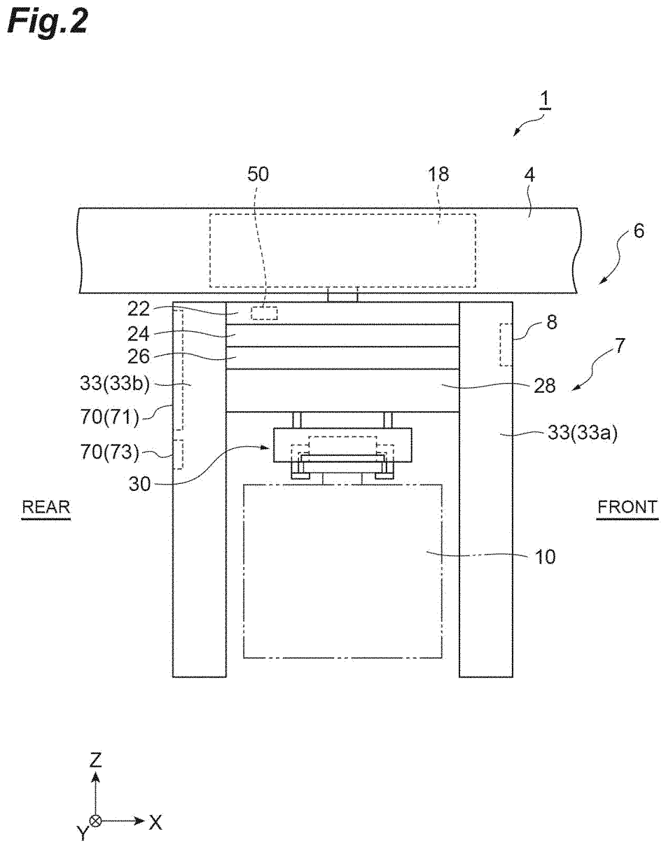

As illustrated in FIG. 2, the track 4 may positioned near the ceiling that is an overhead space located above workers, for example. The track 4 is suspended from the ceiling, for example. The track 4 is a predetermined traveling path along which the traveling vehicles 6 travel.

As illustrated in FIG. 1 and FIG. 2, the placement portions 9 are arranged along the track 4 and are provided at locations where delivery of the article 10 to and from the traveling vehicle 6 is possible. The placement portions 9 each include a buffer and a delivery port. The buffer is a placement portion on which the article 10 is placed temporarily. The buffer is a placement portion on which the article 10 is temporarily placed when, due to, for example, another article 10 being placed on an intended delivery port and the like, the article 10 that the traveling vehicle 6 is transporting cannot be transferred to the delivery port. The delivery port is a placement portion to perform delivery of the article 10 to and from a semiconductor processing apparatus (not depicted) including a cleaning device, a film-forming device, a lithography device, an etching device, a heat treatment device, and a flattening device. The processing apparatus is not particularly limited and may include various devices.

For example, the placement portions 9 are arranged on the lateral side of the track 4. In this case, the traveling vehicle 6 delivers the article 10 to and from the placement portion 9, by laterally feeding an elevating drive portion 28 and the like by a lateral feed portion 24 and by raising and lowering an elevating table 30. Although not depicted, the placement portion 9 may be arranged directly below the track 4. In this case, the traveling vehicle 6 delivers the article 10 to and from the placement portion 9 by raising and lowering the elevating table 30.

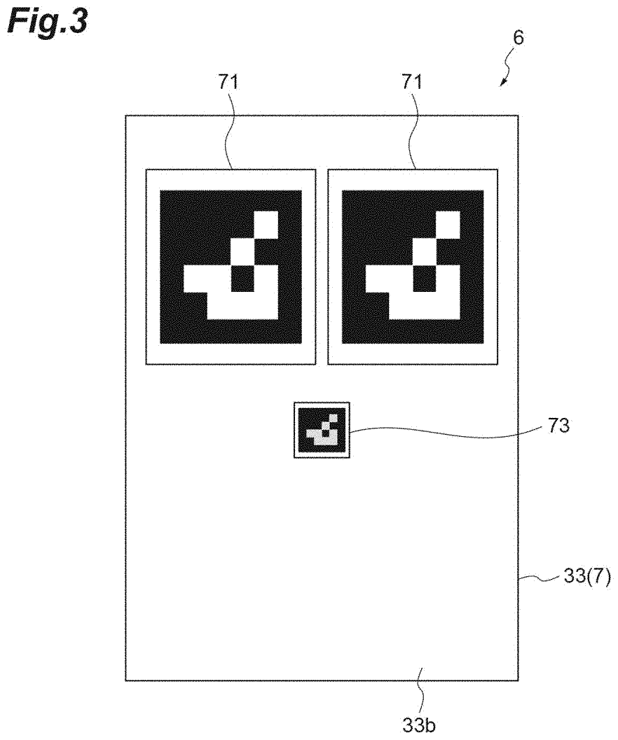

As illustrated in FIG. 2, the traveling vehicle 6 travels along the track 4 and transports the article 10. The traveling vehicle 6 is configured so that the article 10 can be transferred. The traveling vehicle 6 is an overhead-traveling automatic guided vehicle. The number of traveling vehicles 6 included in the traveling vehicle system 1 is not particularly limited and is a plurality. As illustrated in FIG. 2 and FIG. 3, the traveling vehicle 6 includes a traveling portion 18, a main body portion 7, an imager 8, symbols 70, and a controller 50.

The traveling portion 18 includes a motor and the like and causes the traveling vehicle 6 to travel along the track 4. The main body portion 7 includes a main body frame 22, the lateral feed portion 24, a θ drive 26, an elevating drive portion 28, the elevating table 30, and fall prevention covers 33 and 33.

The main body frame 22 supports the lateral feed portion 24, the θ drive 26, the elevating drive portion 28, and the elevating table 30. The lateral feed portion 24 transversely feeds the θ drive 26, the elevating drive portion 28, and the elevating table 30 collectively in a direction perpendicular to the traveling direction of the track 4. The θ drive 26 turns at least one of the elevating drive portion 28 and the elevating table 30 within a predetermined angle range in a horizontal plane. The elevating drive portion 28 raises and lowers the elevating table 30 by winding or feeding out suspending material such as a wire, a rope, and a belt. The elevating table 30 is provided with a chuck, so that the article 10 can be freely grasped or released. The fall prevention covers 33 prevent the article 10 from falling during transport by making claws and the like not depicted appear and disappear. The fall prevention covers 33 include a front cover 33a and a rear cover 33b provided at the front and rear of the traveling vehicle 6 in the traveling direction.

The imager 8 is provided on the front cover 33a of the main body portion 7 so that the image capturing range is in front of the traveling vehicle 6. The imager 8 is a device that includes a lens, an imaging element that converts the light entered from the lens into an electrical signal, and the like. The captured image acquired by the imager 8 is acquired by the controller 50 which will be described in detail in a subsequent stage.

As illustrated in FIG. 3, the symbols 70 are provided on the rear cover 33b of the traveling vehicle 6 so as to be visible from a following traveling vehicle 6 located behind the traveling vehicle 6. The symbols 70 may include a pair of large area symbols (large symbols) 71 and 71 and a small area symbol (small symbol) 73 having an area smaller than each of the pair of large area symbols 71 and 71.

Each of the pair of large area symbols 71 and 71 has a size that does not entirely fit within the image capturing range of the imager 8 provided in or on the following traveling vehicle 6 located less than a predetermined distance (for example, about 0.5 m) from the traveling vehicle 6. The pair of large area symbols 71 and 71 are arrayed in the left-and-right direction on the upper side of the rear cover 33b. The large area symbol 71 may be a graphic including two colors (monochrome).

The small area symbol 73 has a size that entirely fits within the image capturing range of the imager 8 provided in or on the following traveling vehicle 6 even if the distance between the traveling vehicle 6 and the following traveling vehicle 6 is less than the above-described predetermined distance. The small area symbol 73 is provided below the pair of large area symbols 71 and 71 provided on the upper side of the rear cover 33b. The small area symbol 73 may be a graphic including two colors (monochrome). The small area symbol 73 may be directly provided on the rear cover 33b, or a plate or the like on which the small area symbol 73 is provided may be fixed to the rear cover 33b. The small area symbol 73 is not limited to being provided below the large area symbols 71 and 71 and may be provided above, for example.

In this case, “the small area symbol 73 entirely fits within the image capturing range” includes not only the case of being captured in a size that is extracted (recognized) by a determiner 51 which will be described in detail at a subsequent stage but also the case of being captured in a size that is not extracted (recognized) by the determiner 51. That is, the position where the small area symbol 73 is placed only needs to be included in the image capturing range. In addition, it does not matter whether the focus is matched. Moreover, “even if the distance is less than the above-described predetermined distance” in this case may be the case where the distance at which the traveling vehicles 6 and 6 in front and rear can come close to each other is a lower limit value.

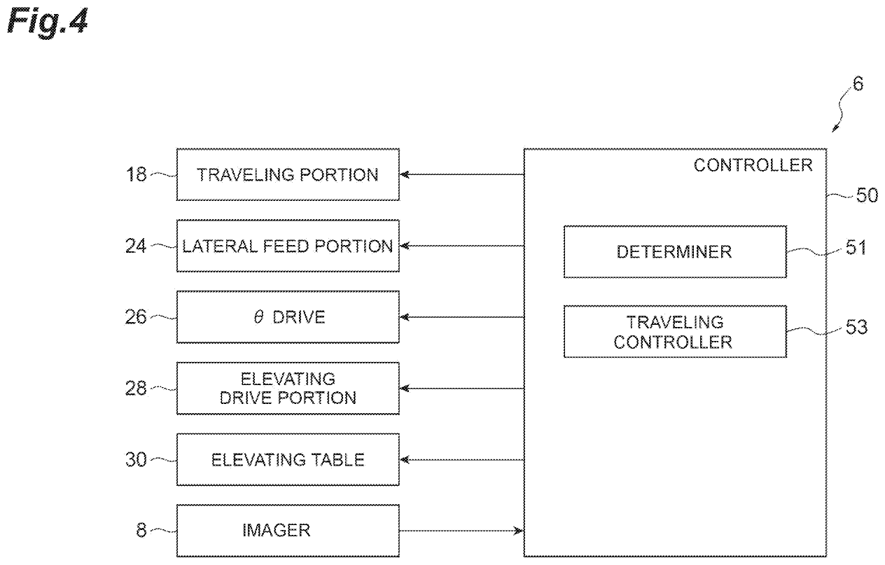

The controller 50 is an electronic control unit including a CPU (Central Processing Unit), a ROM (Read Only Memory), a RAM (Random Access Memory), and the like. The controller 50 is configured or programmed to control various operations in the traveling vehicle 6. Specifically, as illustrated in FIG. 4, the controller 50 controls the traveling portion 18, the lateral feed portion 24, the θ drive 26, the elevating drive portion 28, and the elevating table 30. The controller 50 can be configured as software for which a program stored in the ROM is loaded onto the RAM and executed by the CPU, for example. The controller 50 may be configured as hardware by an electronic circuit or the like. In the controller 50, as the hardware such as the CPU, the RAM, and the ROM and the software such as the program collaborate with each other, the determiner 51 and a traveling controller 53 as illustrated below are provided. The controller 50 performs communication with a controller 60 via a communication line (feeder line) or the like of the track 4.

The determiner 51 tries to extract the symbols 70 from the captured image acquired by the imager 8 and also determines, based on whether the symbols 70 have been extracted, whether a preceding traveling vehicle 6 is present. The determiner 51 determines that, when at least one of each of the entire large area symbols 71 and 71 and the entire small area symbol 73 was extracted from the captured image, the preceding traveling vehicle 6 is present.

In more detail, the determiner 51 determines that it is in a first state when only at least one of the large area symbols 71 and 71 was able to be extracted, is in a second state when the small area symbol 73 and at least one of the large area symbols 71 and 71 were able to be extracted, and is in a third state when only the small area symbol 73 was able to be extracted. Then, the determiner 51 determines that the distance from the traveling vehicle 6 to the preceding traveling vehicle 6 when determined to be in the second state is closer than when determined to be in the first state, and determines that the distance from the traveling vehicle 6 to the preceding traveling vehicle 6 when determined to be in the third state is closer than when determined to be in the second state.

The traveling controller 53 controls the traveling portion 18, when determined to be in the first state, so as to travel at a first speed slower than a normal moving speed, for example. The traveling controller 53 controls the traveling portion 18, when determined to be in the second state, so as to decelerate to a second speed that is slower than the first speed and is a speed at which stopping is allowed at any time. The traveling controller 53 controls the traveling portion 18, when determined to be in the third state, so as to stop completely. This control is one example and one aspect of a preferred embodiment of the present invention is not limited to the above-described method.

The controller 60 is an electronic control unit including a CPU, a ROM, a RAM, and the like. The controller 60 can be configured as software for which a program stored in the ROM is loaded onto the RAM and executed by the CPU, for example. The controller 60 may be configured as hardware by an electronic circuit or the like. The controller 60 transmits a transport command that causes the traveling vehicle 6 to transport the article 10.

Next, a traveling vehicle detection method that is performed by the controller 50 will be described.

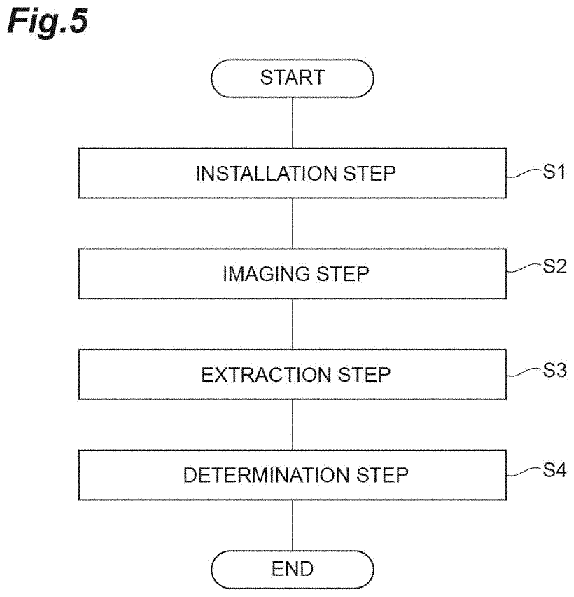

The traveling vehicle detection method is a method of detecting and determining a preceding traveling vehicle 6, based on a captured image acquired by the imager 8 positioned such that the image capturing range is in front of the traveling vehicle 6. As illustrated in FIG. 5, on the rear cover 33b that is a portion of the traveling vehicle 6 visible from a following traveling vehicle 6 located behind the traveling vehicle 6, the large area symbols 71 and the small area symbol 73 are provided (Step S1: installation step).

The large area symbol 71 has a size that does not entirely fit within the image capturing range of the imager 8 provided in or on the following traveling vehicle 6 located at a position at which a distance from the traveling vehicle 6 is less than a predetermined distance (for example, about 0.5 m). The small area symbol 73 has a size that entirely fits within the image capturing range of the imager 8 provided in or on the following traveling vehicle 6 even if the distance between the following traveling vehicle to the traveling vehicle 6 is less than the above-described predetermined distance. In the installation step S1, the two large area symbols 71 and 71 are positioned side by side and the small area symbol 73 is positioned below the large area symbols 71 and 71. The large area symbols 71 may be installed by directly providing on the rear cover 33b or may be installed by fixing a plate or the like on which the large area symbols 71 are provided on the rear cover 33b. In addition, a display such as an LED (Light Emitting Diode) and an LCD (Liquid Crystal Display) may be installed on the rear cover 33b, and the large area symbols 71 and the small area symbol 73 may be displayed as the image displayed on this display.

Next, the imager 8 captures an image of a traveling vehicle 6 in front (Step S2: imaging step). The image capturing by the imager 8 may be executed at predetermined intervals (control period), for example. Then, the controller 50 tries extraction of the entire large area symbols 71 and 71 and the entire small area symbol 73 from the captured image (Step S3: extraction step). Specifically, the controller 50 executes, based on a concordance rate calculated by a known method such as pattern matching, the extraction of the entire large area symbols 71 and 71 and the entire small area symbol 73.

Then, the controller 50, in the extraction step S2, determines that, when at least one of the entire large area symbols 71 and 71 and the entire small area symbol 73 was extracted, the preceding traveling vehicle 6 is present (Step S4: determination step).

Next, the operation and effect of the traveling vehicle system 1 of the above-described first preferred embodiment will be described. Generally, the image capturing range of the imager 8 is wider relative to the detection range of a distance sensor. In the traveling vehicle 6 in the above-described first preferred embodiment, the imager 8 with a wider image capturing range relative to the range of capturing the traveling vehicle 6 in front by conventional sensors provided corresponding to each section of the linear section and the curved section is provided. Thus, without providing each of the distance sensors corresponding to each of the linear section and the curved section as in the conventional case, the preceding traveling vehicle 6 located in both sections can be captured by a single imager 8. Meanwhile, in the configuration of the above-described first preferred embodiment, although the imager 8 itself does not perform the function of measuring the distance, the determiner 51 that determines the distance from the traveling vehicle 6 to the preceding traveling vehicle 6 based on the captured image of the large area symbols 71 and 71 and the small area symbol 73 of the preceding traveling vehicle 6 by the imager 8 acquires the distance from the traveling vehicle 6 to the preceding traveling vehicle 6. This allows a single imager 8 to perform a function equivalent to that of the conventional sensor provided to correspond to each section of the linear section and the curved section. As a result, cost reduction can be achieved.

In the traveling vehicle system 1 of the above-described first preferred embodiment, the determiner 51 may determine that it is in the first state when only the large area symbol 71 was able to be extracted, is in the second state when both the small area symbol 73 and the large area symbol 71 were able to be extracted, and is in the third state when only the small area symbol 73 was able to be extracted, and may determine that the distance from the traveling vehicle 6 to the preceding traveling vehicle 6 when determined to be in the second state is shorter than when determined to be in the first state and that the distance from the traveling vehicle 6 to the preceding traveling vehicle 6 when determined to be in the third state is shorter than when determined to be in the second state. In this configuration, even when the imager 8 does not perform a function of measuring the distance is used, the distance to the preceding traveling vehicle 6 can be acquired in a range of three stages (long distance, medium distance, short distance).

In the traveling vehicle system 1 of the above-described first preferred embodiment, because the small area symbol 73 includes a graphic including two colors, the determiner 51 is able to easily extract the symbol as the small area symbol 73 from the captured image.

In the traveling vehicle system 1 of the above-described first preferred embodiment, because the large area symbols 71 and 71 include a graphic including two colors, the determiner 51 is likely to easily extract the symbols as the large area symbols 71 and 71 from the captured image.

In the traveling vehicle system 1 of the above-described first preferred embodiment, because two of the large area symbols 71 and 71 are provided on the rear cover 33b, the information obtained from the large area symbols 71 and 71 can be provided with redundancy. This enables the determiner 51 to acquire the information more accurately from the large area symbols 71 and 71.

### Second Preferred Embodiment

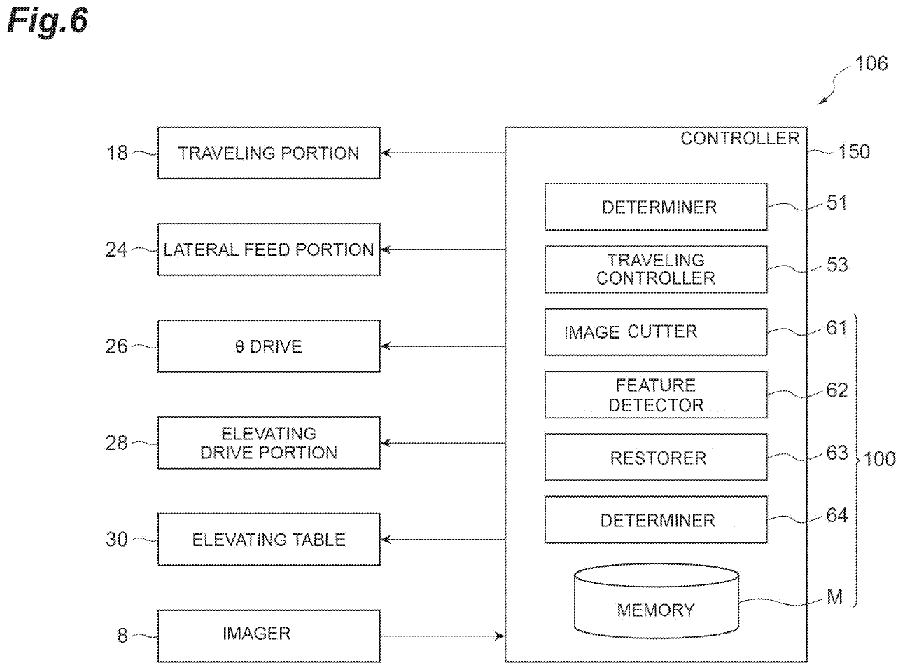

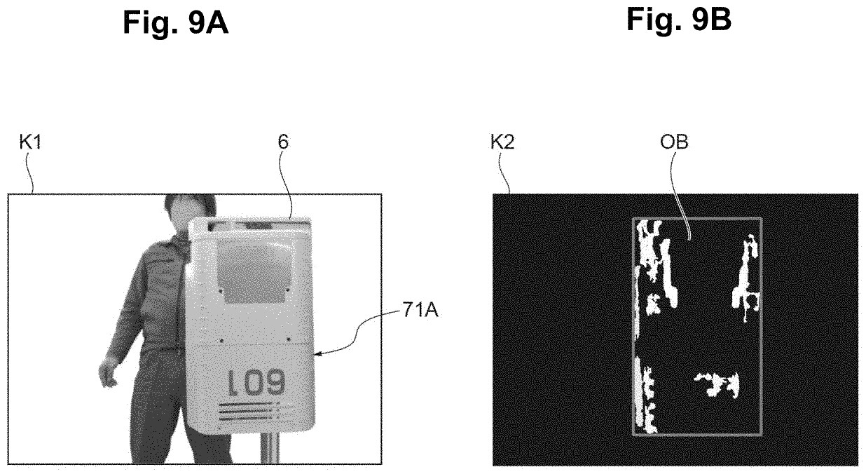

Next, with reference to FIG. 1, FIG. 2, and FIG. 6 to FIGS. 11A and 11B mainly, a second preferred embodiment of the present invention will be described. In the second preferred embodiment, only the portions different from those of the first preferred embodiment will be described in detail and the descriptions of the same portions will be omitted. In a traveling vehicle 106 of the second preferred embodiment, there are three points that significantly differ from those of the traveling vehicle 6 of the first preferred embodiment. The first point is that the imager 8 acquires a distance image. The second point is that, while the graphics including two colors are the large area symbols 71 and 71 in the first preferred embodiment, the appearance of the rear cover 33b is a large area symbol 71A (see FIG. 9A) in the second preferred embodiment. The third point is that a controller 150 of the second preferred embodiment is configured or programmed to perform, in addition to the functions of the controller 50 of the first preferred embodiment, a function of recognizing an appearance image of the rear cover 33b of the traveling vehicle 106. The following describes the controller 150 that is different from the first preferred embodiment.

As mentioned above, the imager 8 acquires a distance image. Examples of such an imager 8 include devices having a distance measuring function such as a LIDAR (Light Detection and Ranging), a stereo camera, a TOF camera, and a millimeter-wave radar. The image acquired from such a device is also referred to as a distance image, a three-dimensional distance image, or an image having three-dimensional information.

The controller 150 is an electronic controller including a CPU, a ROM, a RAM, and the like. The controller 150 is configured or programmed to control various operations in the traveling vehicle 106. Specifically, as illustrated in FIG. 6, the controller 150 controls the traveling portion 18, the lateral feed portion 24, the θ drive 26, the elevating drive portion 28, and the elevating table 30. The controller 150 can be configured as software for which a program stored in the ROM is loaded onto the RAM and executed by the CPU, for example. The controller 150 may be configured as hardware by an electronic circuit or the like. In the controller 150, as the hardware such as the CPU, the RAM, and the ROM and the software such as the program collaborate with each other, the above-described determiner 51 and the traveling controller 53 are provided.

The controller 150 is configured or programmed to define and function as, in addition to the determiner 51 and the traveling controller 53, an image recognizer 100 that recognizes an appearance image of the rear cover 33b of the traveling vehicle 106. In more detail, as the hardware such as the CPU, the RAM, and the ROM and the software such as the program collaborate, the controller 150 defines and functions as the image recognizer 100 by an image cutter 61, a feature detector 62, a restorer 63, a determiner 64, and a memory M illustrated below.

The memory M stores therein each of a plurality of image features detected (extracted) from the appearance image of the rear cover 33b as a portion in advance. The method for detecting image features from a specific image is not particularly limited, and various known methods can be used. For example, by passing the appearance image of the rear cover 33b through an image filter, the image features may be detected. The memory M stores in advance a label given to each of a plurality of portions together with the portion as a portion label. The portion functions, as will be described later, as a seed for image restoration by the restorer 63.

The image feature defines the feature of an image and is also referred to as a feature amount or a feature point of the image. The acquisition of a plurality of portions may be performed by using a learned model (AI: artificial intelligence) obtainable by deep learning. The label indicates information for identifying a target object. The label is not particularly limited and may be a number, for example.

The image cutter 61 cuts out an input image from the captured image acquired by the imager 8. Specifically, the image cutter 61 assumes, as an object (object candidate), a point cloud (a block of points having a similar distance) for which the depth distance is within a predetermined range in the captured image. The image cutter 61 cuts out, as an input image, an image of the object in the captured image. The predetermined range is not particularly limited and can be set in advance. The cutting of the input image from the captured image may be performed by using a learned model (AI: artificial intelligence) obtainable by deep learning, such as Yolo V3, for example.

The feature detector 62 detects a plurality of image features from the input image. The method for detecting image features from the input image is not particularly limited, and various known methods can be used. For example, the feature detector 62 may detect the image features by passing the input image through an image filter. The feature detector 62 provides a selection label as a label to each of the image features. The feature detector 62 detects the feature intensity of each of the image features. The feature intensity is an index indicating the strength with which the image feature is related to the input image. The feature intensity can indicate the degree that the image feature contributes to in the input image.

The restorer 63 selects the portion corresponding to each of the image features detected in the feature detector 62 from the memory M. The restorer 63 selects the portions having the portion label that matches with the selection label of the image features detected in the feature detector 62 from the memory M. The restorer 63 generates a restoration image by using the plurality of selected portions. The restorer 63 generates the restoration image by further using the feature intensity of the image features detected in the feature detector 62. The method for generating a restoration image using a plurality of portions is not particularly limited, and various known methods such as an auto-encoder configured with a deep neural network, for example, can be used.

The determiner 64 determines whether the restoration image generated in the restorer 63 matches with the input image by a matching process. The determiner 64 recognizes that, when determined that the restoration image matches with the input image, the input image is the appearance image of the rear cover 33b. The matching process is not particularly limited, and various known methods such as the L2 norm, for example, can be used. The determiner 64 may calculate the similarity of the restoration image to the input image and determine that, when the similarity is greater than or equal to a threshold value, the restoration image matches with the input image.

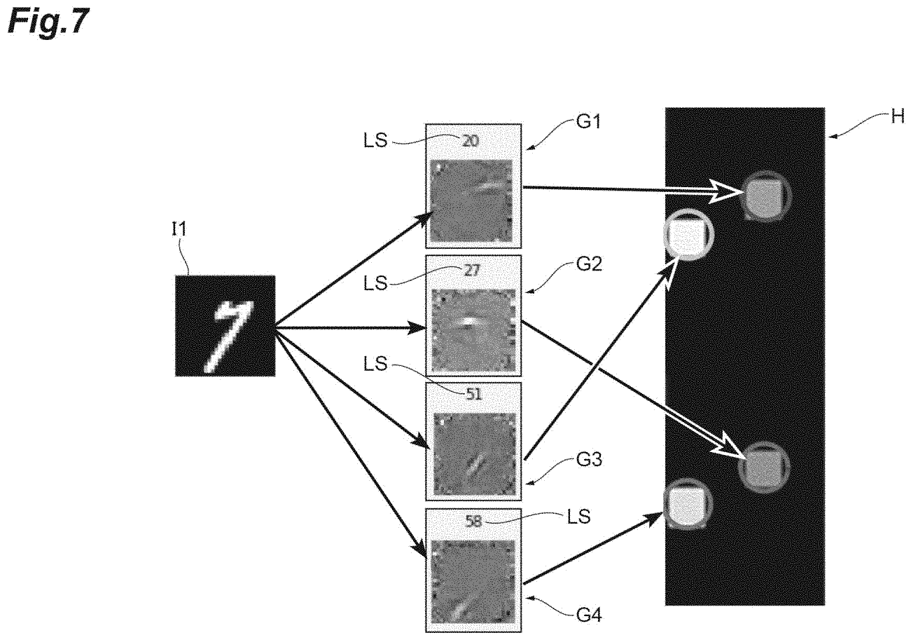

Next, one example of detecting a plurality of image features from the input image by the feature detector 62 will be described with reference to FIG. 7.

As illustrated in FIG. 7, in the description of this case, an image of “numeral 7” is used as the input image, for convenience. With the feature detector 62, a plurality of image features are detected from an input image I1. In the illustrated example, an image feature G1 with a selection label LS of “20”, an image feature G2 with a selection label LS of “27”, an image feature G3 with a selection label LS of “51”, and an image feature G4 with a selection label LS of “58” are detected. Then, these are acquired as an image-feature detection result H. In the image-feature detection result H, the feature intensity of each of the image features G1 to G4 is indicated as brightness. In this way, a plurality of image features G1 to G4 can be mechanically detected from the input image I1.

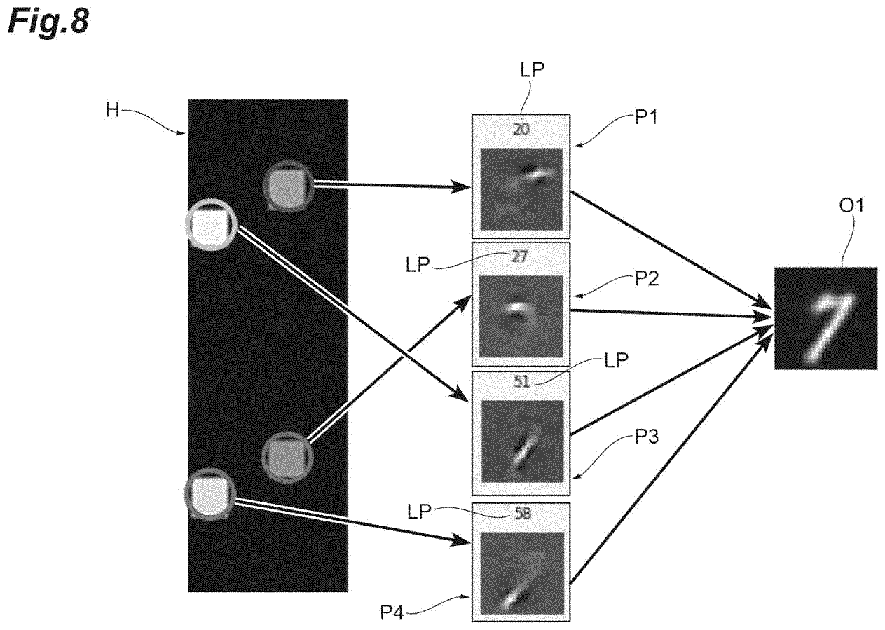

Next, one example of restoring an image by the restorer 63 based on the image features G1 to G4 will be described with reference to FIG. 8.

As illustrated in FIG. 8, by the restorer 63, based on the image-feature detection result H, portions P1 to P4 of portion labels LP matching with the selection labels LS of the image features G1 to G4 (see FIG. 7) are selected from the memory M. With the restorer 63, a restoration image O1 is generated using a plurality of selected portions P1 to P4. In this way, the restoration image O1 can be restored from the image features G1 to G4.

Next, one example of recognizing a specific image by an image recognition method performed by the above-described image recognizer 100 will be described. In the following description, a case of recognizing the appearance of the rear cover 33b of the traveling vehicle 106 as a specific image will be exemplified.

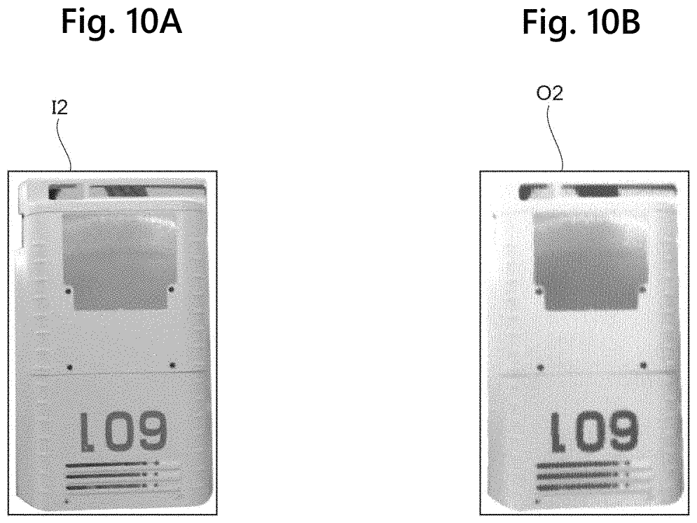

As illustrated in FIG. 9A, with the imager 8, a captured image K1 including the traveling vehicle 106 located in front of the traveling vehicle 106 is acquired. As illustrated in FIG. 9B, with the image cutter 61, depth distance data K2 in the captured image K1 is calculated and a point cloud for which the depth distance is within a predetermined range is assumed as an object OB. As illustrated in FIG. 9A and FIG. 10A, an image of the object OB in the captured image K1 is cut out as an input image I2.

As illustrated in FIG. 10B, a plurality of image features are detected from the input image I2 by the feature detector 62, and a restoration image O2 is generated by the restorer 63. With the determiner 64, whether the restoration image O2 of FIG. 10B matches with the input image I2 is determined by the matching process. In the example illustrated in FIGS. 10A and 10B, it is determined that the restoration image O2 matches with the input image I2 (similarity is greater than or equal to the threshold value), and the input image I2 is recognized as the specific image (appearance image of the rear cover 33b of the traveling vehicle 106).

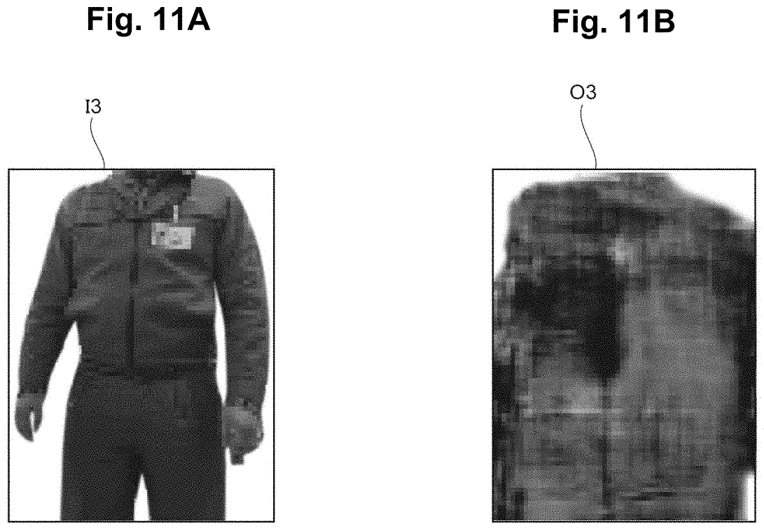

Meanwhile, as illustrated in FIG. 11A, when an image other than the appearance of the rear cover 33b of the traveling vehicle 106 (for example, an image of a body of a user and the like) is input as an input image I3, as illustrated in FIG. 11B, a restoration image O3 generated by the restorer 63 is not what the input image I3 is restored and has significant image collapse and blurring. Thus, in this example, it is determined that the restoration image O3 does not match with the input image I3 (similarity is less than the threshold level), and the input image I3 is not recognized as the specific image (appearance image of the rear cover 33b of the traveling vehicle 106).

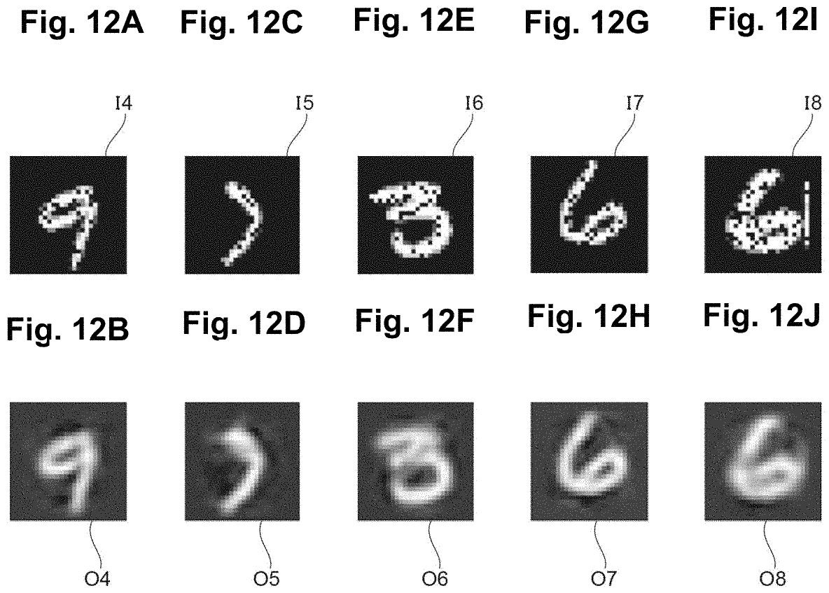

FIGS. 12A to 12J are each a diagram for explaining the robustness of the feature detector 62 and the restorer 63 against noise. According to the image recognizer 100 and the image recognition method thereof, a plurality of image features can be detected from an input image I4 (see FIG. 12A) by the feature detector 62, and a restoration image O4 (see FIG. 12B) can be generated by the restorer 63. A plurality of image features can be detected from an input image I5 (see FIG. 12C) by the feature detector 62, and a restoration image O5 (see FIG. 12D) can be generated by the restorer 63. A plurality of image features can be detected from an input image I6 (see FIG. 12E) by the feature detector 62, and a restoration image O6 (see FIG. 12F) can be generated by the restorer 63. A plurality of image features can be detected from an input image I7 (see FIG. 12G) by the feature detector 62, and a restoration image O7 (see FIG. 12H) can be generated by the restorer 63. A plurality of image features can be detected from an input image I8 (see FIG. 12I) by the feature detector 62, and a restoration image O8 (see FIG. 12J) can be generated by the restorer 63. From these results, according to the image recognizer 100 and the image recognition method thereof, it can be confirmed that, they have the ability to capture the features even if the input images I4 to I8 have noise and that the restoration images O4 to O8 are generated accurately.

As in the foregoing, in the image recognizer 100, when generating the restoration image, the portions detected from the specific image are used. Thus, the image is restored in patterns indicated in the following (i), (ii), and (iii).

(i) When the specific image is an input image, the input image is accurately restored as a restoration image.

(ii) When an input image other than the specific image is input, the input image and the restoration image do not match.

(iii) In particular, when an incorrect image that has image features of the specific image but is not the specific image is input as an input image, the specific image is restored as the restoration image while the input image and the restoration image do not match.

Thus, according to the image recognizer 100, determining whether the input images I1 to I8 match with the restoration images O1 to O8 makes it possible to determine the match or mismatch between the input images I1 to I8 and the specific images (whether the input images I1 to I8 are the specific images or other images) with high accuracy. That is, it is possible to recognize the specific image with high accuracy. On the input images I1 to I8, only determining being the specific image if the image features of the specific image are satisfied will result in misrecognition in the case of the above-described (iii), but in the image recognizer 100 and the image recognition method thereof, such misrecognition can be avoided.

The determiner 51 determines that, when at least one of the entire large area symbol 71A and the entire small area symbol 73 was extracted from the captured image, the preceding traveling vehicle 106 is present. The recognition of the large area symbol 71A is performed by the above-described image recognizer 100 and, based on the recognition result of the image recognizer 100 that recognizes the appearance image of the rear cover 33b, the determiner 51 extracts the large area symbol 71A. The extraction method of the small area symbol 73 is the same as that of the above-described first preferred embodiment and thus the explanation is omitted. The control in the determiner 51 that determines the first state, the second state, and the third state based on the extraction result of the large area symbol 71A and the small area symbol 73, and the control in the traveling controller 53 that controls the traveling portion 18 based on the determination results are also the same as those of the above-described preferred embodiment, and thus the explanation is omitted.

Even in the configuration of the traveling vehicle 106 in the above-described second preferred embodiment, the same effects as those of the traveling vehicle 6 in the above-described first preferred embodiment can be obtained. Moreover, in the second preferred embodiment, because the entire back surface and lateral surface image of the preceding traveling carriage can be used as a symbol, it is possible to perform longer distance and robust detection, as compared with the first preferred embodiment.

As in the foregoing, the preferred embodiments of the present invention have been described, but the preferred embodiments of the present invention are not limited to the above-described preferred embodiments, and various modifications can be made without departing from the spirit of the invention.

### First Modification

In the traveling vehicle 6 and the traveling vehicle system 1 of the above-described first preferred embodiment, an example has been described in which the imager 8 including a lens, an imaging element that converts the light entered from the lens into an electrical signal, and the like, the imager 8 having no function of measuring the distance to and from a target object, is provided, but the preferred embodiments of the present invention are not limited thereto. In the imager 8, devices having a distance measuring function such as a LIDAR (Light Detection and Ranging), a stereo camera, a TOF camera, and a millimeter-wave radar may be used, as in the second preferred embodiment.

In this case, it is possible to accurately acquire the distance to an obstacle not provided with the above-described large area symbol 71 and the small area symbol 73. This makes it possible to also play a role as an obstacle sensor generally provided in the traveling vehicle 6. As a result, a single imager 8 can also function as a conventional linear inter-vehicle sensor, a curved inter-vehicle sensor, and an obstacle sensor, so that further cost reduction can be achieved.

### Second Modification

In the above-described preferred embodiments, the input image has been cut out from the captured image as a distance image, but such an image cutting process and an image cutter 61 may be not provided. As the imager 8, a general single-lens camera may be used, for example. The input image may be a distance image or may be a two-dimensional image.

### Third Modification

In the traveling vehicle 6 and the traveling vehicle system 1 of the above-described preferred embodiments and the modifications, the examples in which at least one of the large area symbols 71 and 71 and the small area symbol 73 includes a two-color graphic have been described, but it may be a two-dimensional code, for example. Examples of the two-dimensional code include a QR code (registered trademark), for example. In this case, as it is possible to acquire more information from the large area symbols 71 and 71 and the small area symbol 73, the determiner 51 can control the traveling vehicle 6 more finely. As one example, as the preceding traveling vehicle 6 can be identified by including a unique number in the QR code, the traveling state or position of the preceding traveling vehicle can be transmitted to the controller 60. Thus, even when the traveling vehicle 6 does not respond to the controller 60 due to the reasons of communication failure or the like, the controller 60 can understand the state of the preceding traveling vehicle 6 by the information given from the following traveling vehicle 6.

Moreover, the large area symbols 71 and 71 and the small area symbol 73 may be an AR marker that is one kind of two-dimensional code. In this case, the determiner 51 can calculate the relative distance to the preceding traveling vehicle 6. That is, as in the above-described preferred embodiment, as compared with the case where the distance to the preceding traveling vehicle 6 is acquired in a range such as being in a long distance range (first state), a medium distance range (second state), or a short distance range (third state), the more accurate distance can be calculated. In the traveling vehicle 6 and the traveling vehicle system 1 in the third modification, the determiner 51 can acquire the relative distance to and from the preceding traveling vehicle 6, so that the traveling vehicle 6 can be controlled more finely.

### Other Modifications

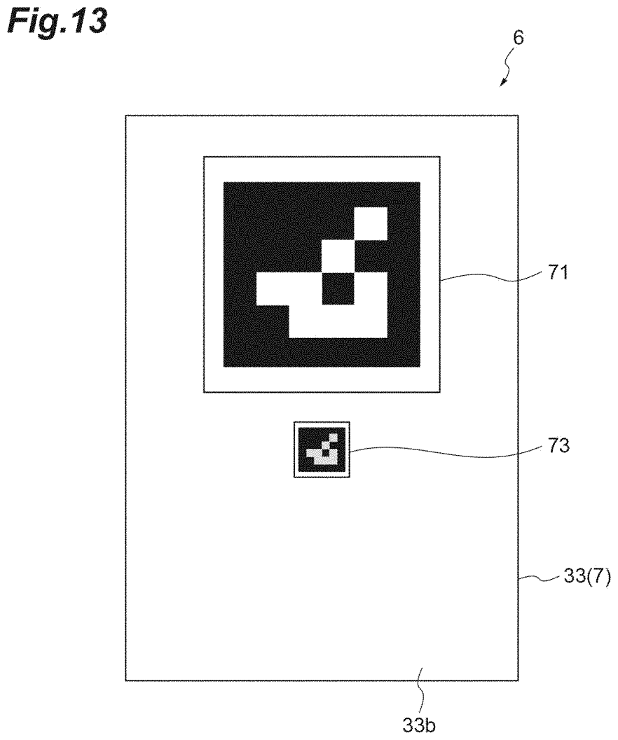

In the traveling vehicle 6 and the traveling vehicle system 1 of the above-described preferred embodiments and modifications thereof, an example where two large area symbols 71 and 71 are provided has been described, but as illustrated in FIG. 13, only one may be provided.

In the above-described preferred embodiments and modifications thereof, an example in which the controller 50 that controls the traveling vehicle 6 (106) is provided in the main body portion 7 of the individual traveling vehicle 6 (106) has been described, but it may be separated from the main body portion 7 and placed at a position operable to perform communication by wire or wirelessly (for example, controller 60). In such a case, the controller 50 may be not provided for each of a plurality of traveling vehicles 6 (106) but provided as a controller that collectively controls the traveling vehicles 6.

In the traveling vehicle 6 (106) and the traveling vehicle system 1 in the above-described preferred embodiments and modifications thereof, an overhead traveling vehicle has been exemplified as one example of the traveling vehicle, but other examples of the traveling vehicle include unmanned vehicles, stacker cranes, and the like that travel on a track laid out on the ground or a frame.

The traveling vehicle 6 of the above-described preferred embodiments and modifications thereof has been exemplified with an example in which the large area symbol 71 and the small area symbol 73 are provided on the rear cover 33b, but the installation position does not matter as long as it is a position visible from the following traveling vehicle 6 (106).

While preferred embodiments of the present invention have been described above, it is to be understood that variations and modifications will be apparent to those skilled in the art without departing from the scope and spirit of the present invention. The scope of the present invention, therefore, is to be determined solely by the following claims.

1-13. (canceled)

14: A traveling vehicle capable of traveling along a predetermined traveling path, the traveling vehicle comprising:
a main body portion provided with a symbol visible from a following traveling vehicle located behind the traveling vehicle;
an imager provided in or on the main body portion so that an image capturing range is in front of the traveling vehicle; and
a determiner to attempt an extraction of the symbol from a captured image acquired by the imager and to determine, based on the whether the symbol has been extracted, whether a preceding traveling vehicle located in front of the traveling vehicle is present; wherein
the main body portion is provided with, as the symbol, a large symbol and a small symbol having a smaller area than that of the large symbol;
the large symbol has a size that does not entirely fit within an image capturing range of an imager in or on the following traveler vehicle located less than a predetermined distance from the traveling vehicle;
the small symbol has a size that entirely fits within the image capturing range of the imager in or on the following traveling vehicle even if a distance between the traveling vehicle and the following traveling vehicle is less than the predetermined distance; and
the determiner is configured or programmed to determine that, when at least one of an entirety of the large symbol and an entirety of the small symbol is extracted from the captured image, the preceding traveling vehicle is present.

15: The traveling vehicle according to claim 14, wherein
the determiner is configured or programmed to determine that the determiner is in a first state when only the large symbol was able to be extracted, is in a second state when both the small symbol and the large symbol were able to be extracted, and is in a third state when only the small symbol was able to be extracted; and
the determiner is configured or programmed to determine that the distance between the traveling vehicle and the preceding traveling vehicle when determined to be in the second state is shorter than when determined to be in the first state and that the distance from the traveling vehicle to the preceding traveling vehicle when determined to be in the third state is shorter than when determined to be in the second state.

16: The traveling vehicle according to claim 14, wherein the small symbol includes a graphic including two colors.

17: The traveling vehicle according to claim 14, wherein the small symbol includes a two-dimensional code.

18: The traveling vehicle according to claim 14, wherein the small symbol includes an augmented reality marker capable of providing to the determiner a distance to the imager.

19: The traveling vehicle according to claim 14, wherein the large symbol includes a graphic including two colors.

20: The traveling vehicle according to claim 14, wherein the large symbol includes a two-dimensional code.

21: The traveling vehicle according to claim 14, wherein the large symbol includes an augmented reality marker capable of providing to the determiner a distance to the imager.

22: The traveling vehicle according to claim 14, wherein a plurality of the large symbols is provided in or on the main body portion.

23: The traveling vehicle according to claim 22, wherein
the main body portion includes a front surface portion and a rear surface portion in front and rear of a traveling direction of the traveling vehicle;
the large symbol includes an appearance of the rear surface portion;
the determiner is configured or programmed to extract the large symbol based on a recognition result of an image recognizer that recognizes an appearance image of the rear surface portion; and
the image recognizer includes:
a memory to store each of a plurality of image features detected from the appearance image of the rear surface portion as a portion in advance;
a feature detector to detect a plurality of image features from an input image;
a restorer to select the portion corresponding to each of the image features detected in the feature determiner from the memory and to generate a restoration image by using the plurality of selected portions; and
a determiner configured or programmed to determine whether the restoration image generated in the restorer matches the input image by a matching process and to recognize that, when determined that the restoration image matches the input image, the input image is the appearance image of the rear surface portion.

24: The traveling vehicle according to claim 14, wherein the imager includes at least one of a Light Detection and Ranging device, a stereo camera, a Time of Flight camera, and a millimeter-wave radar.

25: A traveling vehicle system comprising a plurality of the traveling vehicles according to claim 14.

26: A traveling vehicle detection method of detecting a preceding traveling vehicle located in front of a traveling vehicle, based on a captured image acquired by an imager positioned in or on the traveling vehicle such that an image capturing range of the imager is in front of the traveling vehicle, the method comprising:
installing, at a region of the traveling vehicle visible from a following traveling vehicle located behind the traveling vehicle, a large symbol having a size that does not entirely fit within an image capturing range of an imager located in or on the following traveling vehicle located less than a predetermined distance from the following traveling vehicle, and a small symbol having a size that entirely fits within the image capturing range of the imager provided in or on the following traveling vehicle even if a distance between the traveling vehicle and the following traveling vehicle is less than the predetermined distance;
acquiring a captured image of the preceding traveling vehicle by the imager of the traveling vehicle;
attempting to extract an entirety of the large symbol and an entirety of the small symbol from the captured image; and
determining that, when at least one of the entirety of the large symbol and the entirety of the small symbol is extracted, the preceding traveling vehicle is present.
